(19) United States
(12) Patent Application Publication
(10) Pub. No.: US 2013/0048059 A1
(43) Pub. Date: Feb. 28, 2013

(54) SOLAR CELL, THE PHOTOELECTRIC CONVERSION EFFICIENCY OF WHICH IS IMPROVED BY MEANS OF ENHANCED ELECTRIC FIELDS

(71) Applicants: Sung-Hwan Han, Seoul (KR); Wonjoo Lee, Pocheon-si (KR); SunKi Min, Seoul (KR)

(72) Inventors: Sung-Hwan Han, Seoul (KR); Wonjoo Lee, Pocheon-si (KR); SunKi Min, Seoul (KR)

(73) Assignee: LUMINANO CO., LTD., Seoul (KR)

(21) Appl. No.: 13/558,107

(22) Filed: Jul. 25, 2012

Related U.S. Application Data
(63) Continuation of application No. PCT/KR2011/000419, filed on Jan. 21, 2011.

(30) Foreign Application Priority Data
Jan. 25, 2010 (KR) 10-2010-0006626

(51) Int. Cl. H01L 31/02; B82Y 99/00

(52) U.S. Cl. 136/252; 977/948

(57) ABSTRACT

The present invention relates to a thin film solar cell having a photoactive layer interposed between two electrodes, wherein at least one of the two electrodes has an electric field emission layer including nanostructures having electric field emission effects. As the thin film solar cell of the present invention has electrodes with the above-described electric field emission layer, electrons and holes generated by the photoactive layer from light can be effectively delivered to each electrode, thereby improving the photoelectric conversion efficiency of the solar cell.

### CROSS-REFERENCE TO RELATED APPLICATION

This application is a Continuation of International Application No. PCT/KR2011/000419 filed Jan. 21, 2011, which claims the benefits of Korean Patent Application No. 10-2010-0006626 filed Jan. 25, 2010. The entire disclosure of the prior application is incorporated herein by reference in its entirety.

### TECHNICAL FIELD

The present disclosure relates to a solar cell having a photoactive layer interposed between two electrodes, at least one of which has an electric field emission layer including a nanostructure having electric field emission effects.

### BACKGROUND ART

A solar cell is a device that generates electrons and holes from absorbed light and separates and transfers these electrons and holes to a cathode and a anode, thereby generating electromotive power and electric current. The transfer of the electrons is proportional to voltage applied to the both electrodes and inversely proportional to inner resistance. In generating electromotive power from light, conventionally, a silicon-based solar cell formed of p-n type inorganic semiconductors has high efficiency. Although the market for the silicon solar cell has been greatly increased, the silicon solar cell has a limit on improving economic feasibility. Accordingly, there have been suggested many attempts to improve the silicon solar cell. As representatives, a solar cell using a silicon thin film and a compound solar cell formed of CdTe, CuInSe, and Cu(In,Ga)Se or others have been greatly improved. Techniques of an organic solar cell using organic polymers, a dye-sensitized solar cell using dye, and a solar cell using quantum dots have been developed, and, thus, economic feasibility of solar cells have been improved.

As a solar cell has been developed from a silicon p-n junction type to a thin-film multilayer type, an efficiency of the solar cell is greatly affected by characteristics of an interface. Particularly, as the number of interfaces is increased, inner resistance is greatly increased and the efficiency of the solar cell is decreased. In order to increase the efficiency, there have been many attempts to reduce the inner resistance by properly arranging the interfaces between films. When the inner resistance is decreased, photoelectric current is increased and the efficiency is increased. As another method for increasing the photoelectric current, there has been used a method in which voltage between interfaces is increased. In order to do so, energy levels of conduction bands and valance bands of semiconductors used in the solar cells need to be controlled to be maximized. However, if there is a big difference in energy, the efficiency can be decreased. Therefore, the difference in the energy cannot be increased without limitation.

### DISCLOSURE OF THE INVENTION

### Problems to Be Solved by the Invention

The present inventors has achieved the present disclosure by developing a technique in which to effectively deliver electrons and holes in a solar cell, an electric field emission layer including a nanostructure made of a material having great electric field emission effects is provided in an electrode, and, thus, an electric field can be enhanced by the electric field emission layer and a photoelectric current of the solar cell can be increased.

Thus, the present disclosure provides a solar cell having a photoactive layer interposed between two electrodes, at least one of which has an electric field emission layer including a nanostructure having electric field emission effects. As the solar cell has electrodes with the above-described electric field emission layer, electrons and holes generated by the photoactive layer from light can be effectively delivered to each electrode, so that a photoelectric current of the solar cell can be increased and a photoelectric conversion efficiency of the solar cell can be improved accordingly.

However, the problems to be solved by the present disclosure are not limited to the above description and other problems can be clearly understood by those skilled in the art from the following description.

### Means for Solving the Problems

In accordance with one aspect of the present disclosure, there is provided a solar cell comprising a first electrode and a second electrode provided to face each other; a photoactive layer interposed between the two electrodes; and an electric field emission layer provided between the first electrode and the photoactive layer and/or between the second electrode and the photoactive layer, and including a nanostructure.

### Effect of the Invention

In the solar cell in accordance with an illustrative embodiment, at least one of electrodes has an electric field emission layer including a nanostructure and electric field emission effects of the electric field emission layer including a nanostructure cause an increase in an electric field of the electric field emission layer, resulting in effectively delivering electrons and holes generated from light to each electrode and improving a photoelectric conversion efficiency of the solar cell. Further, the electric field emission layer including a nanostructure, such as a carbon nanotube or others, having conductivity can improve the photoelectric conversion efficiency of the solar cell by a decrease in sheet resistance affected by the conductivity, work functions of the conductive nanostructure, and an increase in an electron delivery effect affected by an energy arrangement of the electrodes and, for example, a n-type material conduction band.

### BRIEF DESCRIPTION OF THE DRAWINGS

FIG. 1 provides a cross sectional view of a solar cell in accordance with an illustrative embodiment.

FIGS. 2 and 3 provide electron micrographs of a compound semiconductor solar cell and graphs of an electric field emission effect, respectively, in accordance with an example.

FIGS. 4A and 4B provide electron micrographs of a dye-sensitized solar cell and a graph of an electric field emission effect in accordance with an example.

FIGS. 5 and 6 provide electron micrographs of a quantum dot-sensitized solar cell and a graph (scale bar=3 μm) of an electric field emission effect, respectively, in accordance with an example.

FIGS. 7A and 7B provides electron micrographs of a photoelectrochemical solar cell and a graph of an electric field emission effect in accordance with an example.

FIG. 8 illustrates a molecular level solar cell in accordance with an illustrative embodiment.

FIG. 9 provides electron micrographs of a CuInGaSe compound solar cell in accordance with an example.

FIG. 10 provides electron micrographs of an organic-inorganic hybrid solar cell in accordance with an example.

### BEST MODE FOR CARRYING OUT THE INVENTION

In accordance with an aspect of the present disclosure, there is provided a solar cell including: a first electrode and a second electrode provided to face each other; a photoactive layer interposed between the two electrodes; and an electric field emission layer that is provided between the first electrode and the photoactive layer and/or between the second electrode and the photoactive layer, and includes a nanostructure.

In some illustrative embodiments, the nanostructure may include, but are not limited to, a nanorod, a nanowire or a nanotube.

In other illustrative embodiments, the electric field emission layer may include a nanostructure selected from the group consisting of, for example, but not limited to, a metal, an organic material, an inorganic material, an organo-metallic compound, an organic-inorganic hybrid, and combinations thereof. By way of example, the electric field emission layer may include one or more nanostructures selected from the group consisting of, but not limited to, an oxide nanotube, an oxide nanorod, chalcogenide, a metal nanotube, a metal nanorod, a carbon nanotube, a carbon nanorod, a carbon nanofiber, a graphene, an etched silicon, a silicon nanotube, a silicon nanowire, an organo-metallic compound nanotube, an organo-metallic compound nanorod, a organo-metallic compound nanowire, an organic nanotube, an organic nanorod, an organic nanowire, an organic-inorganic hybrid nanotube, an organic-inorganic hybrid nanotube nanorod, an organic-inorganic hybrid nanotube nanowire, and combinations thereof.

In still other illustrative embodiments, the solar cell may be, but is not limited to, a thin film solar cell.

In still other illustrative embodiments, at least one of the first electrode and the second electrode may be, but is not limited to, a transparent electrode. Any one of transparent electrodes may be used as the transparent electrode without limitation if it is used in manufacturing a solar cell in the art. By way of example, the transparent electrode may be formed on a transparent substrate. The transparent substrate may include, for example, but not limited to, a glass substrate or a plastic substrate. The transparent electrode may be made of a transparent conducive material. By way of example, if the transparent electrode serves as a cathode (electron acceptor), it may include, but is not limited to, various conductive oxides including indium tin oxide (ITO), F-doped tin oxide (FTO), zinc oxide (ZnO), antimony-doped tin oxide (ATO), phosphorous-doped tin oxide (PTO), antimony-doped zinc oxide (AZO), indium-doped zinc oxide (IZO) and a chalcogenide compound. By way of example, if the transparent electrode serves as a counter electrode to the cathode, it may include, but is not limited to, transparent conductive materials such as various conductive oxides including ITO, FTO, ZnO, IZO, ATO, and AZO and a chalcogenide compound or a layer of metal, such as Pd, Ag, and Pt, formed on the transparent conductive materials.

In still other illustrative embodiments, the electric field emission layer may be, but is not limited to, between the photoactive layer and an electrode serving as a cathode of the first electrode and the second electrode.

In still other illustrative embodiments, the electric field emission layer may be formed by means of, but not limited to, a spray coating method, an impregnation method, a spraying method, a liquid-phase growth method or a vapor-phase growth method.

In still other illustrative embodiments, the electric field emission layer may further include, but is not limited to, an adhesive agent.

The solar cell may include all kinds of solar cells known in the art. That is, in the solar cell including a first electrode and a second electrode provided to face each other, a photoactive layer interposed between the two electrodes, and an electric field emission layer including a nonostructure provided between the first electrode and the photoactive layer and/or between the second electrode and the photoactive layer, and includes a nanostructure, the photoactive layer may include a certain material and a certain form which has been known in the art or will be developed in the future. The solar cell may be classified into, for example, but not limited to, a compound semiconductor solar cell, a dye-sensitized solar cell, a silicon solar cell, a quantum dot solar cell, a molecular level solar cell, an organic solar cell, or an organic-inorganic hybrid solar cell depending on the material and the form of the photoactive layer. Except the electric field emission layer, components, materials, and manufacturing methods of the above-described solar cells may be employed without limitation from those known in the art.

In an illustrative embodiment, the solar cell may be a compound semiconductor solar cell including:

A first electrode and a second electrode provided to face each other;

A photoactive layer interposed between the two electrodes and includes one or more compound semiconductor layers; and

An electric field emission layer provided between the first electrode and the photoactive layer and/or between the second electrode and the photoactive layer, and including a nanostructure.

As a non-limiting example, the photoactive layer may include, but is not limited to, two or more compound semiconductor layers having different conductivity types.

As a non-limiting example, the photoactive layer may include, but is not limited to, one or more n-type compound semiconductor layers, one or more p-type compound semiconductor layers or combinations thereof. The n-type compound semiconductor layer and the p-type compound semiconductor layer may include one or more compound semiconductors known in the art.

As a non-limiting example, the n-type compound semiconductor layer may include, but is not limited to, a compound semiconductor that is made of a chalcogenide compound or an oxide containing one or more elements selected from the group consisting of Ti, Zn, Sn, Nb, W, Ta, In, V, Ni, Zr, Cu, Ga, Mo, Fe, Si, As, C, and N and has a conduction band positioned lower than the p-type compound semiconductor layer; or a compound semiconductor that is made of an organic material, an organic polymer, an organic-inorganic hybrid or an organo-metallic compound and has a conduction band positioned lower than the p-type compound semiconductor layer.

As a non-limiting example, the p-type compound semiconductor layer may include, but is not limited to, a compound semiconductor that is made of a chalcogenide compound or an oxide containing one or more elements selected from the group consisting of Ti, Zn, Sn, Nb, W, Ta, In, V, Ni, Zr, Cu, Ga, Mo, Fe, Si, As, C, and N and has a valance band positioned higher than the n-type compound semiconductor layer; or a compound semiconductor that is made of an organic material, an organic polymer, an organic-inorganic hybrid or an organo-metallic compound and has a valance band positioned higher than the n-type compound semiconductor layer.

As a non-limiting example, the compound semiconductor layers may further include, but are not limited to, one or more light absorptive layers therebetween. The light absorptive layer may include one or more elements selected from the group consisting of, for example, an organic material, an inorganic material, an organo-metallic compound, an organic-inorganic hybrid, and combinations thereof and may have a lowest unoccupied molecular orbital (LUMO) or energy level of a conduction band between the conduction band of the p-type semiconductor layer and the conduction band of the n-type semiconductor layer, but the present disclosure is not limited thereto.

In another illustrative embodiment, the solar cell may be a silicon solar cell including:

A first electrode and a second electrode provided to face each other;

A photoactive layer interposed between the two electrodes, and including an n-type silicon layer and a p-type silicon layer; and

An electric field emission layer provided between the first electrode and the photoactive layer and/or between the second electrode and the photoactive layer, and including a nanostructure.

Except the electric field emission layer, other components of the silicon solar cell may be employed without limitation from those known in the art.

In an illustrative embodiment, the solar cell may be a dye-sensitized solar cell including:

A first electrode and a second electrode provided to face each other;

A photoactive layer to which dye is adsorbed interposed between the two electrodes; and

An electric field emission layer is provided between the first electrode and the photoactive layer and/or between the second electrode and the photoactive layer, and including a nanostructure.

Except the electric field emission layer, other components of the dye-sensitized solar cell may be employed without limitation from those known in the art.

In still another illustrative embodiment, the solar cell may be a quantum dot solar cell including:

A first electrode and a second electrode provided to face each other;

A photoactive layer interposed between the two electrodes, and including a quantum dot, and

An electric field emission layer provided on at least one surface of the first electrode and the second electrode, the surface facing the photoactive layer, and including a nanostructure.

Except the electric field emission layer, other components of the quantum dot solar cell may be employed without limitation from those known in the art.

As a non-limiting example, the quantum dot may have a diameter ranging from about 1 nm to about 10 nm and may have any one functional group selected from the group consisting of, but not limited to, —OH, ═O, —O—, —S—S—, —SH, P═O, —P, and —PH. By way of example, the quantum dot may include one or more compounds selected from the group consisting of, but not limited to, a compound containing a first element selected from Groups 2, 12, 13, and 14 of a periodic table and a second element selected from Group 16; a compound containing a first element selected from Group 13 of the periodic table and a second element selected from Group 15; and a compound containing an element selected from Group 14 of the periodic table. By way of example, the quantum dot may include one or more compounds selected from the group consisting of, but not limited to, CdS, MgSe, MgO, CdO, CdSe, CdTe, InP, InAs, ZnS, ZnSe, ZnTe, HgTe, GaN, GaP, GaAs, GaSb, InSb, Si, Ge, AlAs, AlSb, PbSe, PbS, and PbTe.

In still another illustrative embodiment, the solar cell may be a molecular level solar cell including:

A first electrode and a second electrode provided to face each other;

A photoactive layer interposed between the two electrodes, and including a dye layer and an electron accepting layer; and

An electric field emission layer provided between the first electrode and the photoactive layer and/or between the second electrode and the photoactive layer, and including a nanostructure.

Except the electric field emission layer, other components of the molecular level solar cell may be employed without limitation from those known in the art.

In still another illustrative embodiment, the solar cell may be an organic solar cell including:

A first electrode and a second electrode provided to face each other;

A photoactive layer interposed between the two electrodes, and including a conductive polymer and an electron acceptor; and

An electric field emission layer provided between the first electrode and the photoactive layer and/or between the second electrode and the photoactive layer, and including a nanostructure.

Except the electric field emission layer, other components of the organic solar cell may be employed without limitation from those known in the art.

In still another illustrative embodiment, the solar cell may be an organic-inorganic hybrid solar cell including:

A first electrode and a second electrode provided to face each other;

A photoactive layer interposed between the two electrodes, and including an inorganic semiconductor layer, an n-type conductive polymer layer, and a p-type conductive polymer layer; and

An electric field emission layer provided between the first electrode and the photoactive layer and/or between the second electrode and the photoactive layer, and including a nanostructure.

Except the electric field emission layer, other components of the organic-inorganic hybrid solar cell may be employed without limitation from those known in the art.

A solar cell in accordance with an illustrative embodiment can be manufactured by a method including: providing a first electrode and a second electrode to face each other; providing a photoactive layer to be interposed between the two electrodes; providing an electric field emission layer including nanostructure between the first electrode and the photoactive layer and/or between the second electrode and the photoactive layer.

In some illustrative embodiments, the nanostructure may include, but are not limited to, a nanorod, a nanowire, or a nanotube.

In other illustrative embodiments, the electric field emission layer may include a nanostructure including, for example, but not limited to, a metal, an organic material, an inorganic material, an organo-metallic compound or an organic-inorganic hybrid. By way of example, the electric field emission layer may include one or more nanostructures selected from the group consisting of, but not limited to, an oxide nanotube, an oxide nanorod, a chalcogenide, a metal nanotube, a metal nanorod, a carbon nanotube, a carbon nanorod, a carbon nanofiber, a graphene, anetched silicon, a silicon nanotube, silicon nanowire, an organo-metallic compound nanotube, an organo-metallic compound nanorod, an organo-metallic compound nanowire, an organic nanotube, an organic nanorod, an organic nanowire, an organic-inorganic hybrid nanotube, an organic-inorganic hybrid nanotube nanorod, an organic-inorganic hybrid nanotube nanowire, and combinations thereof.

In still other illustrative embodiments, at least one of the first electrode and the second electrode may be, but is not limited to, a transparent electrode.

In still other illustrative embodiments, the transparent electrode may include, but is not limited to, a carbon nanotube.

In still other illustrative embodiments, the electric field emission layer may be, but is not limited to, between the photoactive layer and an electrode serving as a cathode of the first electrode and the second electrode.

In still other illustrative embodiments, the electric field emission layer may be formed by means of, but not limited to, a spray coating method, an impregnation method, a spraying method, a liquid-phase growth method or a vapor-phase growth method.

In illustrative embodiments, the electric field emission layer may further include, but is not limited to, an adhesive agent.

Hereinafter, illustrative embodiments and examples will be described in detail so that inventive concept may be readily implemented by those skilled in the art.

However, it is to be noted that the present disclosure is not limited to the illustrative embodiments and examples but can be realized in various other ways. In drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

In an illustrative embodiment, the solar cell may include: a first electrode serving as a cathode; an electric field emission layer including a nanostructure provided on the first electrode; a photoactive layer provided on the electric field emission layer; and a second electrode provided on the photoactive layer and serving as a counter electrode. The electric field emission layer may be provided between the photoactive layer and the second electrode.

One or more of the first electrode and the second electrode may be a transparent electrode. The transparent electrode may be provided on a transparent substrate. Further, a metal layer of Pt, Ag, Pd, and the like may be additionally provided on the second electrode serving as the counter electrode.

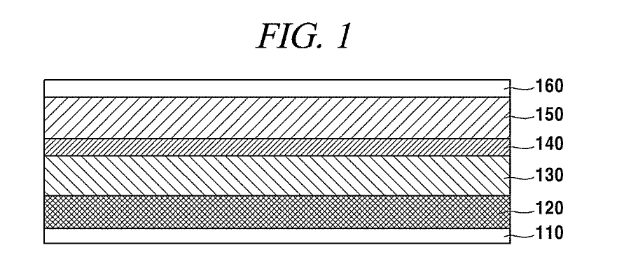

If the solar cell is a compound semiconductor solar cell, the photoactive layer may be formed of, for example, but not limited to, one or more n-type semiconductor layers 130 and one or more p-type semiconductor layers 150 stacked with each other. The one or more n-type semiconductor layers 130 may provided on an electric field emission layer 120 provided on a first electrode 110 serving as a cathode and the one or more p-type semiconductor layers 150 provided on the n-type semiconductor layers 130. However, the present disclosure is not limited thereto. In this case, as a non-limiting example, a light absorptive layer 140 may be additionally provided between the n-type semiconductor layer 130 and the p-type semiconductor layer 150, so that an absorption range of sunlight can be increased (see FIG. 1).

Referring to FIG. 1, each of the first electrode 110 and a second electrode 160 receives electrons and holes generated by a photoelectric conversion effect and delivers them to the outside, and one or both of the electrodes include a transparent electrode that receives and transmits light. The transparent electrode may be made of a material selected from various transparent conductive oxides, such as ITO, FTO, ZnO, ATO, PTO, AZO, and IZO and chalcogenide. A kind of the material does not make a big difference in implementing the present disclosure. In some cases, a carbon nanotube itself may serve as a conductive transparent electrode. A kind of the electrode does not matter.

When the n-type semiconductor layer 130 and the p-type semiconductor layer 150 are stacked with each other, a p-n junction is formed at an interface thereof, and, thus, the solar cell may be configured as a p-n junction solar cell. If necessary, the light absorptive layer 140 capable of absorbing light may be additionally provided between the n-type semiconductor layer 130 and the p-type semiconductor layer 150.

The n-type semiconductor layer 130 and the p-type semiconductor layer 150 may include a compound semiconductor including, but not limited to, an inorganic material, an organic material, an organo-metallic compound, an organic-inorganic hybrid, and combinations thereof.

As a non-limiting example, the n-type compound semiconductor layer may include a compound semiconductor that is made of an oxide containing one or more elements selected from the group consisting of Ti, Zn, Sn, Nb, W, Ta, In, V, Ni, Zr, Cu, Ga, Mo, Fe, Si, As, C, and N or a chalcogenide compound and has a conduction band positioned lower than the p-type compound semiconductor layer, or a compound semiconductor that is made of an organic material, an organic polymer, an organic-inorganic hybrid or an organo-metallic compound and has a conduction band positioned lower than the p-type compound semiconductor layer.

As a non-limiting example, the p-type compound semiconductor layer may include a compound semiconductor that is made of an oxide containing one or more elements selected from the group consisting of Ti, Zn, Sn, Nb, W, Ta, In, V, Ni, Zr, Cu, Ga, Mo, Fe, Si, As, C, and N or a chalcogenide compound and has a valance band positioned higher than the n-type compound semiconductor layer, or a compound semiconductor that is made of an organic material, an organic polymer, an organic-inorganic hybrid or an organo-metallic compound and has a valance band positioned higher than the n-type compound semiconductor layer.

The light absorptive layer 140 may be made of an organic material, an inorganic material, an organo-metallic compound, an organic-inorganic hybrid or combinations of one or more of these materials. As a non-limiting example, the light absorptive layer 140 may include conductive conjugated polymers such as thiophene, aniline, acetylene or combinations thereof. The light absorptive layer 140 may have a single layer or multiple layers. By way of example, two or more light absorption agents having different wavelength absorption ranges may be formed in a multilayered structure in order to effectively absorb a full range of sunlight.

The electric field emission layer 120 may include a nanostructure containing a material capable of improving an electric field to effectively deliver electrons generated at the n-type compound semiconductor layer/(selective light absorptive layer 140)/p-type compound semiconductor layer by absorption of light to the first electrode 110 serving as the cathode. The nanostructure may include a nanotube, a nanorod, and a nanowire having a high aspect ratio of a diameter to a length. The electric field emission layer 120 may be formed of a nanotube, a nanorod or a nanowire made of an organic material, an inorganic material, an organo-metallic compound, and an organic-inorganic hybrid, one or more of which may be combined depending on a purpose of use.

By way of example, the electric field emission layer 120 may include one or more nanostructures selected from the group consisting of an oxide nanotube, an oxide nanorod, a chalcogenide, a metal nanotube, a metal nanorod, a carbon nanotube, a carbon nanorod, a carbon nanofiber, a graphene, an etched silicon, a silicon nanotube, a silicon nanowire, an organo-metallic compound nanotube, an organo-metallic compound nanorod, an organo-metallic compound nanowire, an organic nanotube, an organic nanorod, an organic nanowire, an organic-inorganic hybrid nanotube, an organic-inorganic hybrid nanotube nanorod, an organic-inorganic hybrid nanotube nanowire, and combinations thereof.

As a non-limiting example, the electric field emission layer 120 may include a carbon-based material, metal, an oxide, a chalcogenide-based material, an etched silicon, a silicon nanotube, and a silicon nanowire and the like. By way of example, a carbon nanotube may be used effectively and may selectively include at least of a single wall, a multiple walls, and a carbon nanofiber. In some cases, an additive may be used to easily form the electric field emission layer 120. The additive may include, but is not limited to, carboxyl methyl cellulose (CMC), TiO₂ and the like. Instead of the carbon nanotube, an oxide nanorod, an oxide nanotube, an organo-metallic compound nanotube, an organo-metallic compound nanorod, an organic nanotube, an organic nanorod, an organic nanowire, an organo-metallic compound nanowire, an organic-inorganic hybrid nanotube, an organic-inorganic hybrid nanorod, and an organic-inorganic hybrid nanowire may be used for the same purpose. When metal, oxide such as MgO or chalcogenide is additionally provided thereon, an electric field emission effect can be increased.

Such materials of improving an electric field are easily deposited in form of a nanostructure as described above by various methods such as an impregnation method, a spraying method, a liquid-phase growth method, and a vapor-phase growth method to form the electric field emission layer 120. A degree of increase of an electric field may vary depending on the methods, but there is not a big difference. Nanostructures constituting the electric field emission layer 120 may be regularly or irregularly arranged at random. Even if the nanostructures are irregularly arranged at random, there is no difference in the electric field emission effect.

If the solar cell is a dye-sensitized solar cell, for example, the photoactive layer may include, but is not limited to, a semiconductor layer to which dye is adsorbed, an electrolyte layer including an electron donor or an electrolyte. In this case, the semiconductor layer to which dye is adsorbed may be provided on the electric field emission layer 120 formed on the first electrode 110. Except the electric field emission layer 120, components, materials, and manufacturing methods of the dye-sensitized solar cell may be employed without limitation from those known in the art. By way of example, the semiconductor layer to which dye is adsorbed may be, but is not limited to, a porous transition metal oxide layer, such as a porous TiO₂ layer, to which the dye is adsorbed. The dye may include one or more dyes, without limitation, selected from those known in the art as dyes used for manufacturing a dye-sensitized solar cell. By way of example, the dye may include a metal complex including, but not limited to, aluminum (Al), platinum (Pt), palladium (Pd), europium (Eu), lead (Pb), iridium (Ir), ruthenium (Ru) or combinations thereof. Herein, ruthenium is one of platinum group elements and can form various organo-metallic complexes, and, thus, dye containing ruthenium is generally used. By way of example, Ru(etc bpy)₂(NCS)₂.CH₃CN is generally used. Herein, etc represents a functional group, in the form of (COOEt)₂ or (COOH)₂, capable of being bonded to a surface of the porous transition metal oxide layer such as the porous TiO₂ layer. Further, dye containing an organic pigment may be used. The organic pigment may include coumarin, porphyrin, xanthene, riboflavin, and triphenylmethane. Each of these pigments may be used solely or in combination with a Ru complex to improve absorption of visible light having a long wavelength. Thus, photoelectric conversion efficiency can be further increased.

If the solar cell is an organic-inorganic hybrid solar cell, for example, the photoactive layer may include a mixture or a multilayered structure of a conductive polymer and an inorganic semiconductor. The conductive polymer and the inorganic semiconductor may be employed without limitation from those used in the art for manufacturing an organic-inorganic hybrid solar cell. By way of example, the photoactive layer may include a bulk heterojunction formed by mixing a conductive polymer and C₆₀.

If the solar cell is a quantum dot solar cell, the photoactive layer may include a quantum dot. The quantum dot may be employed without limitation from those used in the art for manufacturing a quantum dot-sensitized solar cell. As a non-limiting example, the quantum dot may have a diameter ranging from about 1 nm to about 10 nm and may have any one functional group selected from the group consisting of —OH, ═O, —O—, —S—S—, —SH, —P═O, —P, and —PH. By way of example, the quantum dot may include one or more compounds selected from the group consisting of a compound containing a first element selected from Groups 2, 12, 13, and 14 of a periodic table and a second element selected from Group 16; a compound containing a first element selected from Group 13 of the periodic table and a second element selected from Group 15; and a compound containing an element selected from Group 14 of the periodic table. By way of example, the quantum dot may include one or more compounds selected from the group consisting of CdS, MgSe, MgO, CdO, CdSe, CdTe, InP, InAs, ZnS, ZnSe, ZnTe, HgTe, GaN, GaP, GaAs, GaSb, InSb, Si, Ge, AlAs, AlSb, PbSe, PbS, and PbTe.

As described above, regardless of a material constituting the photoactive layer for absorbing light, an increase in an electric field caused by an electric field emission effect of the electric field emission layer 120 has the same effect on all kinds of solar cells known in the art. Therefore, photoelectric current can be increased as compared with a case where the electric field emission layer 120 is not provided.

Hereinafter, examples of the present disclosure will be explained in detail, but the present disclosure is not limited thereto.

### Example 1

### Compound Semiconductor Solar Cell Having Electric Field Effect

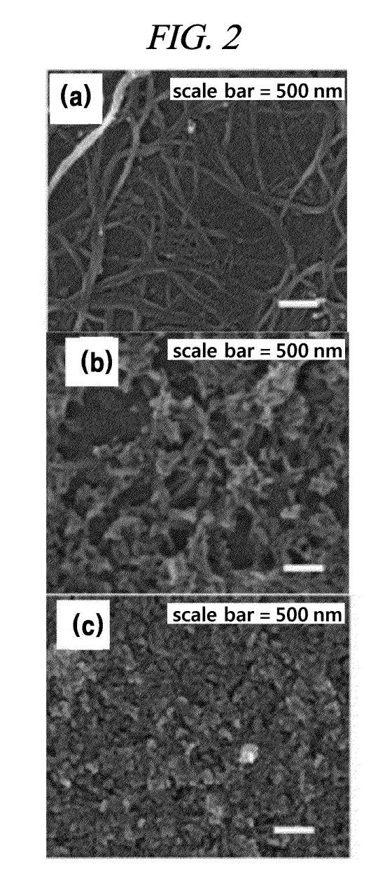

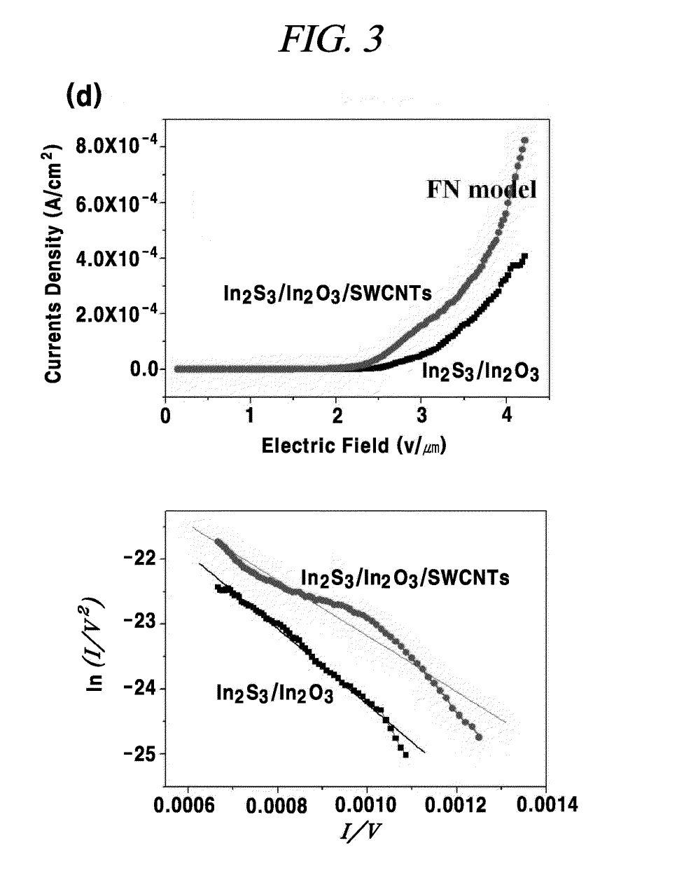

In order to create an electric field effect of a compound semiconductor solar cell, a conductive carbon nanotube (CNT) layer was formed on a conductive transparent substrate, on which an ITO transparent electrode was provided, by a spray coating method so as to form an electric field emission layer (FIG. 2a). The carbon nanotube layer was formed of single walled carbon nanotubes (SWCNTs). Each of an In₂O₃ semiconductor layer (FIG. 2b) and an In₂S₃ semiconductor layer (FIG. 2c) was formed on the carbon nanotube layer by a chemical bath deposition (CBD) method. Then, a conductive transparent substrate, on which an ITO transparent electrode was provided, was provided as a counter electrode, so that a compound semiconductor solar cell was completed by a method typically used in the art. In order to prove that an electric field effect was increased when the carbon nanotube layer, the In₂O₃ layer, and the In₂S₃ layer were stacked in sequence, an electric field emission effect was measured (FIG. 3). As for the solar cell having the electric field emission layer including the carbon nanotube layer, as can be seen from FIG. 3, a beta value was increased, and as can be seen from Table 1, a photoelectric conversion efficiency as an efficiency of the solar cell was increased by about 50% or more, from about 0.17% to about 0.26%. The efficiency of the solar cell can be further increased by increasing a thickness of a compound semiconductor.

TABLE 1

| | In₂S₃/In₂O₃ | In₂S₃/In₂O₃/SWCNTs |
|---|---|---|
| V_{TO} | 2.55 | 2.19 |
| (10 μA/V μ · m⁻¹) | | |
| β value | 3660 | 4950 |

| | V_{oc}(V) | J_{sc}(mA/cm²) | ff | E_{ff}(%) |
|---|---|---|---|---|
| In₂S₃ | 0.24 | 0.31 | 0.40 | 0.03 |
| In₂S₃/In₂O₃ | 0.45 | 0.97 | 0.39 | 0.17 |
| SWCNTs/In₂O₃/In₂S₃ | 0.46 | 1.43 | 0.40 | 0.26 |

### Example 2

### Dye-Sensitized Solar Cell Haying Electric Field Effect

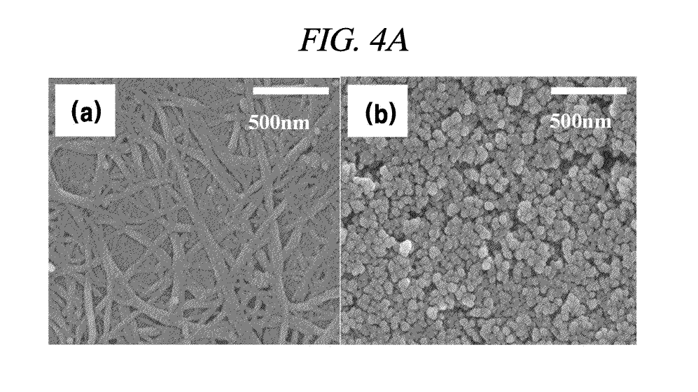

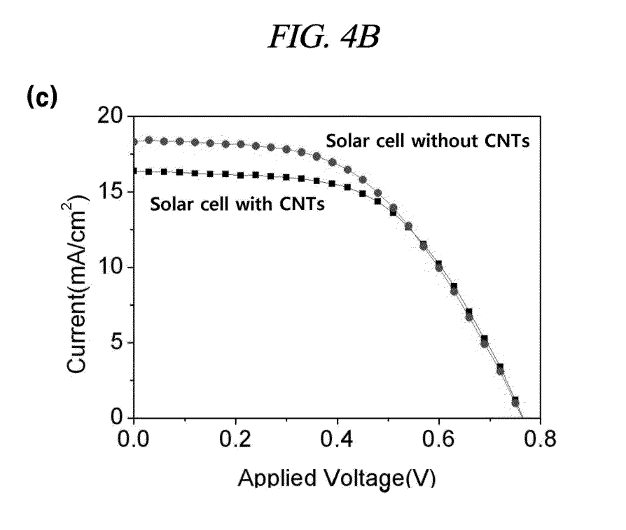

In order to create an electric field effect of a dye-sensitized solar cell, a conductive carbon nanotube layer as an electric field emission layer was formed on a conductive transparent substrate, on which an ITO transparent electrode was provided, by a spray coating method ((a) of FIG. 4A). A TiO₂ thin film was formed on the formed carbon nanotube layer by a screen printing method and photosensitive dye was adsorbed onto the TiO₂ thin film ((b) of FIG. 4A). As the photosensitive dye, an organo-metallic compound (ruthenium (RuL₂(NCS)₂): N₃) was used. Then, a conductive transparent substrate, on which an ITO transparent electrode was provided, was provided and an electrolyte layer was formed, so that a dye-sensitized solar cell was completed. The substrate and the electrolyte were employed from those used in the art for manufacturing a dye-sensitized solar cell. As described above, the manufactured dye-sensitized solar cell had an efficiency of about 6.94% without the carbon nanotube layer as the electric field emission layer for creating the electric field effect and had an efficiency of about 7.17% with the carbon nanotube layer as the electric field emission layer (Table 2).

TABLE 2

| | V_{oc}(V) | J_{sc}(mA/cm²) | ff | E_{ff}(%) |
|---|---|---|---|---|
| Solar cell | 0.77 | 16.38 | 0.55 | 6.94 |
| without CNTs | | | | |
| Solar cell | 0.76 | 18.31 | 0.51 | 7.17 |
| with CNTs | | | | |

### Example 3

### Quantum Dot-Sensitized Solar Cell Having Electric Field Effect

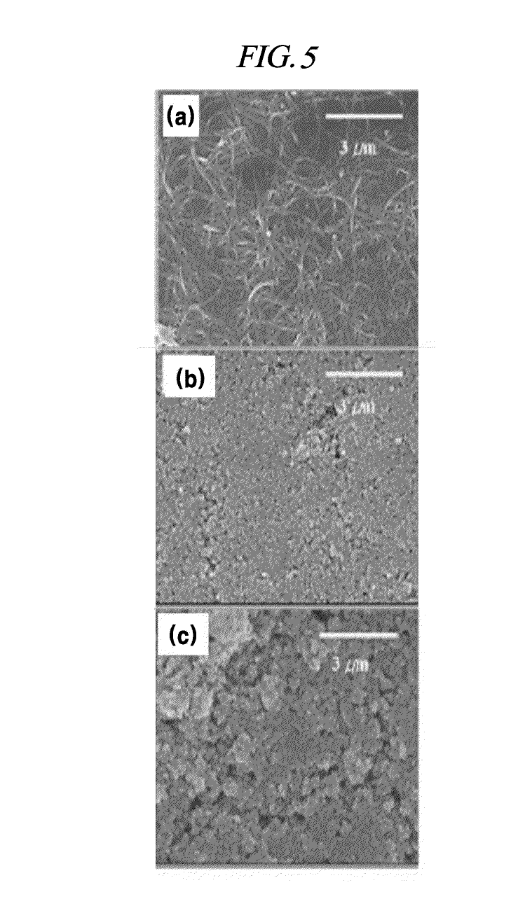

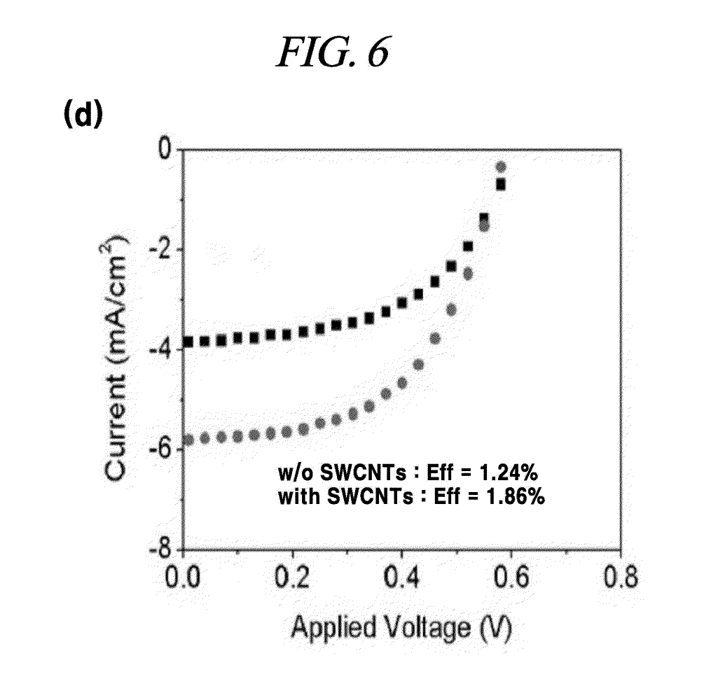

In order to create an electric field effect of a quantum dot-sensitized solar cell, a conductive carbon nanotube layer was formed on a conductive substrate, on which an ITO transparent electrode was provided, by a spray coating method so as to form an electric field emission layer (FIG. 5a). A TiO₂ layer was formed on the carbon nanotube layer by a screen printing method (FIG. 5b). Then, a quantum dot was formed by a chemical bath deposition method (FIG. 5c). As the quantum dot, cadmium sulfide (CdS) quantum dot was used. A conductive substrate, on which an ITO transparent electrode was provided, was provided as a counter electrode. As for the quantum dot-sensitized solar cell having the electric field emission layer including the quantum dot on the transparent electrode, an efficiency of the quantum dot-sensitized solar cell was increased by about 50%, to about 1.86%, as compared with the solar cell without the carbon nanotube layer, by the electric field emission effect illustrated in FIG. 3 (FIG. 6).

### Example 4

### Photoelectrochemical Solar Cell Having Electric Field Effect

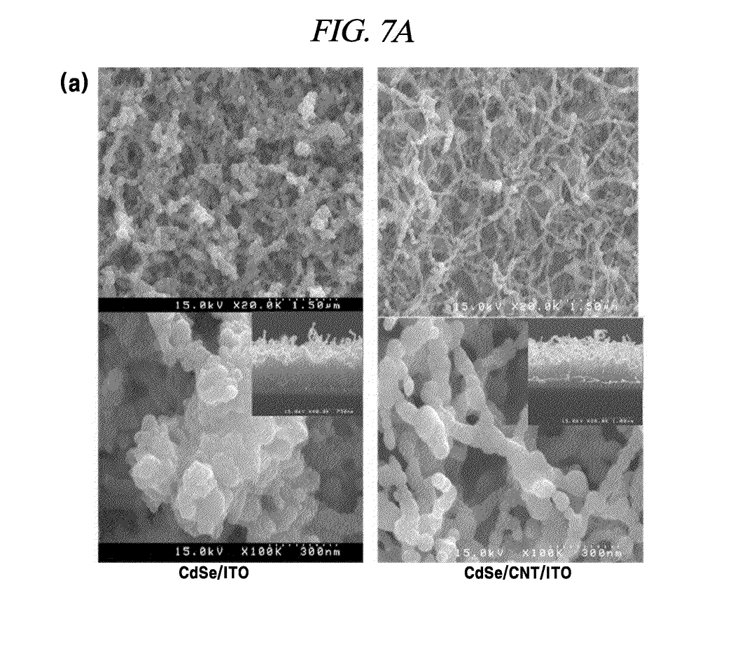

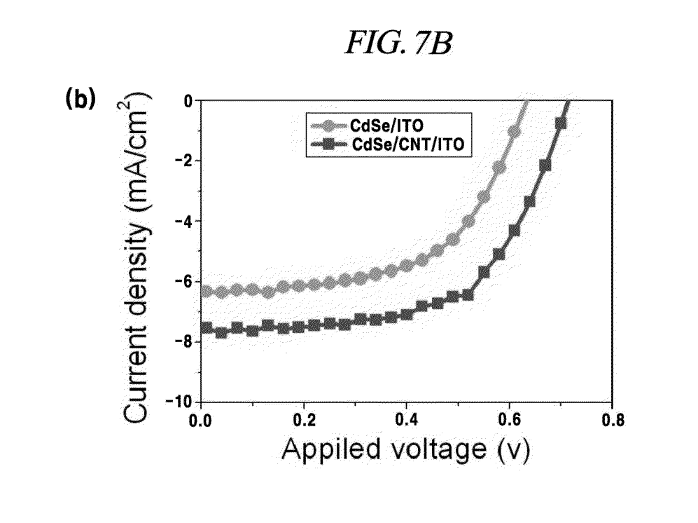

A carbon nanotube layer described in the above examples as an electric field emission layer was formed on a conductive substrate, on which an ITO transparent electrode was provided, and a cadmium selenide (CdSe) layer as a photoactive layer was formed on the carbon nanotube layer. Then, a conductive substrate, on which an ITO transparent electrode was provided, was provided as a counter electrode so as to manufacture a photoelectrochemical solar cell. The cadmium selenide layer was formed by an electrodeposition method (see FIGS. 7A and 7B). When the carbon nanotube and the cadmium selenide layer were stacked in sequence, as can be seen from Table 3, an efficiency of the solar cell was increased by about 46%, from about 2.28% (without the carbon nanotube layer) to about 3.34%, by an enhanced electric field effect (Table 3).

TABLE 3

| | V_{oc}(V) | J_{sc}(mA/cm²) | ff | E_{ff}(%) |
|---|---|---|---|---|
| CdSe/ITO | 0.63 | 6.34 | 0.56 | 2.28 |
| CdSe/CNT/ITO | 0.71 | 7.56 | 0.61 | 3.34 |

### Example 5

### Molecular Level Solar Cell Having Electric Field Effect

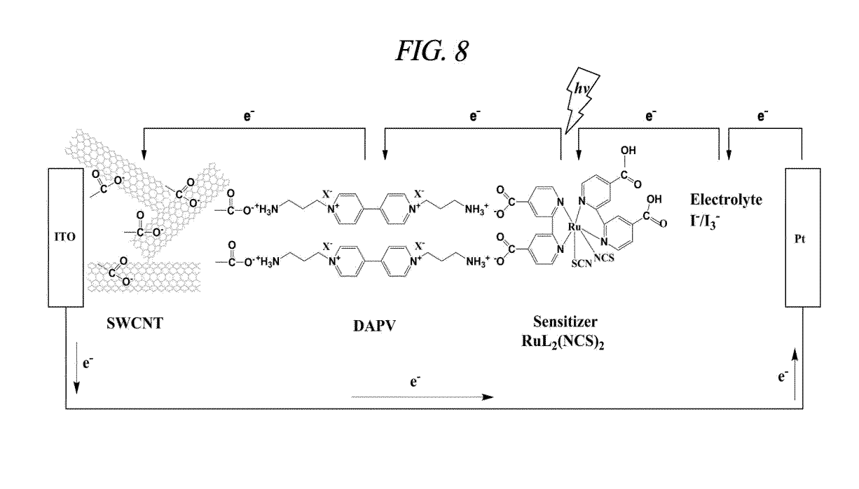

The present example related to a molecular level solar cell. In order to manufacture the molecular level solar cell, a self-assembled monolayer method was used. As a photosensitive material capable of absorbing light, ruthenium (RuL₂(NCS)₂) organo-metallic compound used for the dye-sensitized solar cell was used. FIG. 8 illustrates a molecular level solar cell. In the photosensitive material and an electron donor formed on a carbon nanotube by the self-assembled thin layer method, photoelectric current was increased about two times by an enhanced electric field effect.

### Example 6

### Increase in Electric Field Emission and Efficiency in CuInGaSe Compound Solar Cell Caused by Increase in Electric Field

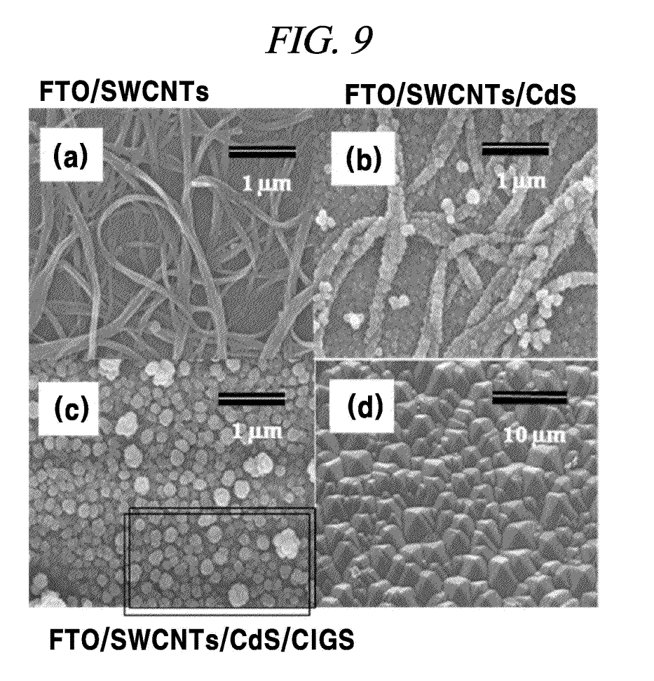

In order to create an electric field effect of a CuInGaSe (CIGS) solar cell, a conductive carbon nanobute layer as an electric field emission layer was formed on a conductive substrate by a spray coating method (FIG. 9a) and a CdS layer of about 100 nm was formed on the substrate by a chemical liquid-phase growth method (FIG. 9b). Then, a CIGS thin film was formed on the CdS layer by an electrochemical method (FIG. 9c). Silicon as a counter electrode was etched (FIG. 9d) and consequent voltage and current were measured (Table 4). When the carbon nanotube was positioned lower than an n-type semiconductor, switch voltage was decreased and particularly, a beta value was increased by about 45%, from about 4252 to about 6166. When a solar cell included this film and a gold electrode as a counter electrode, an efficiency of the solar cell was measured as shown in the following table. When the carbon nanotube layer was not provided, the solar cell had an efficiency of about 8.53%, whereas when the carbon nanotube layer as an electric field emission layer was provided, an efficiency of the solar cell was increased to about 10.60%.

TABLE 4

| | CIGS/CdS/FTO | CIGS/CdS/SWCNTs/FTO |
|---|---|---|
| V_{TO} | 5.64 | 4.53 |
| (10 μA/V μ · m⁻¹) | | |
| β value | 4252 | 6166 |

| | V_{oc}(V) | J_{sc}(mA/cm²) | ff | E_{ff}(%) |
|---|---|---|---|---|
| CIGS/CdS/FTO | 0.61 | −26.9 | 0.52 | 8.53 |
| CIGS/CdS/SWCNTs/FTO | 0.64 | −29.0 | 0.57 | 10.60 |

### Example 7

### Organic-Inorganic Hybrid Solar Cell in Relation to Increase in Electric Field

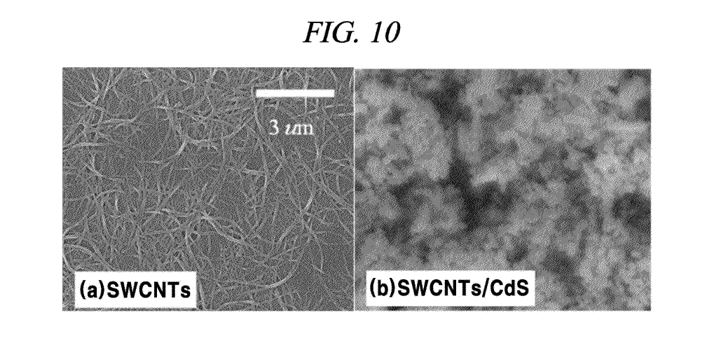

In order to create an electric field effect of an organic-inorganic hybrid solar cell, a conductive carbon nanotube layer as an electric field emission layer was formed on a conductive substrate, on which an ITO transparent electrode was provided, by a spray coating method (FIG. 10a) and a CdS layer of about 100 nm was formed on the substrate by a chemical liquid-phase growth method (FIG. 10b). Then, a thin film of an acetylene-based conductive polymer was coated on the CdS layer. Thereafter, a thiophene-based polymer film as a p-type semiconductor and a metal electrode were formed thereon so as to manufacture a solar cell device. An efficiency of the solar cell was measured as shown in the following table. When the carbon nanotube layer was not provided, the solar cell had an efficiency of about 1.24%, whereas when the carbon nanotube layer as an electric field emission layer was provided, an efficiency of the solar cell was increased by about 50%, to about 1.86%. The efficiency of the solar cell was proportional to a thickness of the CdS layer.

TABLE 5

| | V_{oc}(V) | J_{sc}(mA/cm²) | ff | E_{ff}(%) |
|---|---|---|---|---|
| TiO₂/CdS | 0.61 | 3.84 | 0.54 | 1.24 |
| SWCNTs/TiO₂/CdS | 0.60 | 5.80 | 0.55 | 1.86 |

The present disclosure has been explained in detail with reference to the examples as above, but the present disclosure is not limited to the above-described examples and can be modified and changed in various ways. Thus, it is clear that various changes and modifications may be made by those skilled in the art within the scope of the inventive concept.

What is claimed is:

1. A solar cell comprising:
a first electrode and a second electrode provided to face each other;
a photoactive layer interposed between the two electrodes; and
an electric field emission layer provided between the first electrode and the photoactive layer and/or between the second electrode and the photoactive layer, and including a nanostructure.

2. The solar cell of claim 1, wherein the nanostructure includes a nanorod, a nanowire or a nanotube.

3. The solar cell of claim 1, wherein the electric field emission layer includes the nanostructure selected from the group consisting of metal, an organic material, an inorganic material, an organo-metallic compound, an organic-inorganic hybrid, and combinations thereof.

4. The solar cell of claim 3, wherein the electric field emission layer includes one or more nanostructures selected from the group consisting of an oxide nanotube, an oxide nanorod, chalcogenide, a metal nanotube, a metal nanorod, a carbon nanotube, a carbon nanorod, a carbon nanofiber, a graphene, an etched silicon, a silicon nanotube, a silicon nanowire, an organo-metallic compound nanotube, an organo-metallic compound nanorod, an organo-metallic compound nanowire, an organic nanotube, an organic nanorod, an organic nanowire, an organic-inorganic hybrid nanotube, an organic-inorganic hybrid nanotube nanorod, organic-inorganic hybrid nanotube nanowire, and combinations thereof.

5. The solar cell of claim 1, wherein at least one of the first electrode and the second electrode is a transparent electrode.

6. The solar cell of claim 1, wherein the electric field emission layer is provided between the photoactive layer and an electrode serving as a cathode among the first electrode and the second electrode.

7. The solar cell of claim 1, wherein the electric field emission layer is formed by a spray coating method, an impregnation method, a spraying method, a liquid-phase growth method or a vapor-phase growth method.

8. The solar cell of claim 1, wherein the solar cell includes a compound semiconductor solar cell, a dye-sensitized solar cell, a silicon solar cell, a quantum dot solar cell, a molecular level solar cell, an organic solar cell, or an organic-inorganic hybrid solar cell.

9. The solar cell of claim 1, wherein the electric field emission layer further includes an adhesive agent.

10. A compound semiconductor solar cell comprising:
a first electrode and a second electrode provided to face each other;
a photoactive layer interposed between the two electrodes and including one or more compound semiconductor layers; and
an electric field emission layer provided between the first electrode and the photoactive layer and/or between the second electrode and the photoactive layer, and including a nanostructure.

11. The compound semiconductor solar cell of claim 10, wherein the photoactive layer includes two or more compound semiconductor layers having different conductivity types.

12. The compound semiconductor solar cell of claim 10, wherein the photoactive layer includes one or more n-type compound semiconductor layers, one or more p-type compound semiconductor layers, or combinations thereof.
